(19) United States
(12) Patent Application Publication
(10) Pub. No.: US 2026/0314042 A1
(43) Pub. Date: Oct. 8, 2026

(54) BACKSIDE CONTACT TO DEVICES WITH WIDE SOURCE/DRAIN REGIONS

(71) Applicant: Intel Corporation, Santa Clara, CA (US)

(72) Inventors: Sheng-Po Fang, Vancouver, WA (US); Hwichan Jun, Portland, OR (US); Lee D. Rockford, Portland, OR (US)

(73) Assignee: Intel Corporation, Santa Clara, CA (US)

(21) Appl. No.: 19/171,804

(22) Filed: Apr. 7, 2025

(51) Int. Cl. H10D 84/83; H10D 30/00; H10D 30/01; H10D 30/43; H10D 30/47; H10D 62/10; H10D 62/13; H10D 64/23; H10D 84/01

(52) U.S. Cl. CPC H10D 84/8312; H10D 30/014; H10D 30/017; H10D 30/0191; H10D 30/43; H10D 30/481; H10D 30/502; H10D 62/121; H10D 62/151; H10D 64/254; H10D 84/013; H10D 84/0149; H10D 84/833

(57) ABSTRACT

Techniques are provided herein to form an integrated circuit having semiconductor devices with source or drain regions that are formed using different epitaxial growth profiles. An integrated circuit includes a first semiconductor region extending in a first direction from a first source or drain region, and a second semiconductor region extending in the first direction from a second source or drain region. The second source or drain region may be wider than the first source or drain region along the first direction. The second source or drain region includes a first epitaxial region having one or more epitaxial layers and a second epitaxial region having one or more additional epitaxial layers on the first epitaxial region. Each of the first and second epitaxial regions may include at least one epitaxial layer that is doped with one or more n-type or p-type dopants and at least one layer that is substantially undoped.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Due to the small size of the transistor elements, such as the transistor gate, source, or drain, it can be difficult to provide effective contacts while maintaining desired operation speeds and power requirements. Accordingly, there remain a number of non-trivial challenges with respect to forming such high-density semiconductor devices.

### BRIEF DESCRIPTION OF THE DRAWINGS

FIGS. 1A and 1B are cross-sectional views of different semiconductor devices in an integrated circuit that include different source or drain widths and different epitaxial regions, in accordance with an embodiment of the present disclosure.

FIGS. 2A and 2B are cross-sectional views that illustrate one stage in an example process for forming an integrated circuit having different semiconductor devices with source or drain regions with different epitaxial growth profiles, in accordance with an embodiment of the present disclosure.

FIGS. 3A and 3B are cross-sectional views that illustrate another stage in the example process for forming an integrated circuit having different semiconductor devices with source or drain regions with different epitaxial growth profiles, in accordance with an embodiment of the present disclosure.

FIGS. 4A and 4B are cross-sectional views that illustrate another stage in the example process for forming an integrated circuit having different semiconductor devices with source or drain regions with different epitaxial growth profiles, in accordance with an embodiment of the present disclosure.

FIGS. 5A and 5B are cross-sectional views that illustrate another stage in the example process for forming an integrated circuit having different semiconductor devices with source or drain regions with different epitaxial growth profiles, in accordance with an embodiment of the present disclosure.

FIGS. 6A and 6B are cross-sectional views that illustrate another stage in the example process for forming an integrated circuit having different semiconductor devices with source or drain regions with different epitaxial growth profiles, in accordance with an embodiment of the present disclosure.

FIGS. 7A and 7B are cross-sectional views that illustrate another stage in the example process for forming an integrated circuit having different semiconductor devices with source or drain regions with different epitaxial growth profiles, in accordance with an embodiment of the present disclosure.

FIGS. 8A and 8B are cross-sectional views that illustrate another stage in the example process for forming an integrated circuit having different semiconductor devices with source or drain regions with different epitaxial growth profiles, in accordance with an embodiment of the present disclosure.

FIGS. 9A and 9B are cross-sectional views that illustrate another stage in the example process for forming an integrated circuit having different semiconductor devices with source or drain regions with different epitaxial growth profiles, in accordance with an embodiment of the present disclosure.

FIGS. 10A and 10B are cross-sectional views that illustrate another stage in the example process for forming an integrated circuit having different semiconductor devices with source or drain regions with different epitaxial growth profiles, in accordance with an embodiment of the present disclosure.

FIG. 10B′ is a cross-sectional view that illustrates an alternative epitaxial growth profile for the semiconductor device from FIG. 10B, in accordance with an embodiment of the present disclosure.

FIGS. 11A and 11B are cross-sectional views that illustrate another stage in the example process for forming an integrated circuit having different semiconductor devices with source or drain regions with different epitaxial growth profiles, in accordance with an embodiment of the present disclosure.

FIGS. 12A and 12B are cross-sectional views that illustrate another stage in the example process for forming an integrated circuit having different semiconductor devices with source or drain regions with different epitaxial growth profiles, in accordance with an embodiment of the present disclosure.

FIGS. 13A and 13B are cross-sectional views that illustrate another stage in the example process for forming an integrated circuit having different semiconductor devices with source or drain regions with different epitaxial growth profiles, in accordance with an embodiment of the present disclosure.

FIGS. 14A and 14B are cross-sectional views that illustrate another stage in the example process for forming an integrated circuit having different semiconductor devices with source or drain regions with different epitaxial growth profiles, in accordance with an embodiment of the present disclosure.

FIGS. 15A and 15B are cross-sectional views that illustrate another stage in the example process for forming an integrated circuit having different semiconductor devices with source or drain regions with different epitaxial growth profiles, in accordance with an embodiment of the present disclosure.

FIG. 16 illustrates a cross-sectional view of a chip package containing one or more semiconductor dies, in accordance with some embodiments of the present disclosure.

FIG. 17 is a flowchart of a fabrication process for forming different semiconductor devices with different epitaxial growth profiles, in accordance with an embodiment of the present disclosure.

FIG. 18 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having semiconductor devices with differently sized source or drain regions (e.g., having different widths) that are formed using different epitaxial growth profiles. The techniques can be used in any number of integrated circuit applications and are particularly useful with respect to logic and memory cells, such as those cells that use finFETs or gate-all-around transistors (e.g., ribbonFETs and nanowire FETs) or forksheet transistors. In one such example, an integrated circuit may include a first device having a first semiconductor region extending in a first direction from a first source or drain region, and a second device having a second semiconductor region extending in the first direction from a second source or drain region. The second source or drain region may be wider than the first source or drain region along the first direction, such as at least twice as wide. Epitaxial growth of semiconductor material to form the first source or drain region may not be sufficient to form enough semiconductor material for the second source or drain region. According to some embodiments, an additional epitaxial growth procedure is performed to form another epitaxial region in the second source or drain region. Thus, a first epitaxial region having one or more epitaxial layers may be first formed followed by a second epitaxial region having one or more epitaxial layers on the first epitaxial region. Each of the first and second epitaxial regions may include at least one epitaxial layer that is doped with one or more n-type or one or more p-type dopants and at least one layer that is substantially undoped (e.g., is not deposited with any n-type or p-type dopants). The more robust epitaxial profile for the second source or drain region allows for a backside contact to make better contact with the second source or drain region, according to some embodiments. Numerous variations and embodiments will be apparent in light of this disclosure.

### General Overview

As previously noted above, there remain a number of non-trivial challenges with respect to integrated circuit fabrication. As devices become smaller and more densely packed, the contact area to transistor elements like the source or drain regions becomes smaller as well. Also, integrated devices having different sizes presents its own slate of design challenges. In some examples, logic and memory devices may have a first width while analog mixed signal (AMS) devices may have a wider second width. It can be challenging to form the source or drain regions of the wider AMS devices such that they actually fill the wider source/drain trenches. Wide source or drain regions that do not fill the trenches can lead to higher contact resistance with backside contacts. Some integrated circuit designs use the backside contacts against the bottom surface of the source or drain regions to provide power or signal to the source or drain regions. However, the backside contacts can punch through the thickness of the wide source or drain regions, leading to increased contact resistance and reduced device yield.

Thus, and in accordance with an embodiment of the present disclosure, techniques are provided herein to provide different epitaxial growth profiles for devices with different source or drain widths. According to some embodiments, some devices of a given integrated circuit may have source or drain regions with a first width and other devices may have source or drain regions with a second width greater than the first width, such as at least 1.5 times, 2 times, 2.5 times, or 3 times greater. In some examples, the second width may be greater than 50 nm, such as between 50 nm and 60 nm. In order to form more robust source or drain regions, the source or drain regions with the second width may be formed from at least two epitaxial regions, with each region including one or more epitaxial layers. According to an embodiment, a given source or drain region with the second width includes a first epitaxial region of silicon (Si) for n-channel devices or silicon germanium (SiGe) p-channel devices. The first epitaxial region has at least a first epitaxial layer and a second epitaxial layer on the first epitaxial layer. According to some embodiments, the given source or drain region with the second width also includes a second epitaxial region (of Si or SiGe) on the first epitaxial region. In the above example, the first epitaxial layer may be substantially undoped while the second epitaxial layer is doped with either one or more n-type dopants (for an n-channel device) or one or more p-type dopants (for a p-channel device). In this context, being substantially undoped means that the first epitaxial layer is not deposited with any n-type or p-type dopants. After formation of the given source or drain region, some dopant(s) may diffuse into the first epitaxial layer, but the concentration of the n-type or p-type dopant(s) in the first epitaxial layer will be at least two orders of magnitude lower than the concentration of n-type or p-type dopant(s) in the second epitaxial layer, according to some examples.

According to some embodiments, the second epitaxial region may include a single epitaxial layer having the n-type or p-type dopant(s), or it may include a third epitaxial layer on the second epitaxial layer and a fourth epitaxial layer on the third epitaxial layer. In such examples, the third epitaxial layer may be substantially undoped while the fourth epitaxial layer is doped with either the n-type or the p-type dopant(s) (e.g., same as the second epitaxial layer). A backside contact may be formed beneath the given source or drain region and extend through any number of the epitaxial layers, such as into at least the third epitaxial layer or into the fourth epitaxial layer.

According to an embodiment, an integrated circuit includes a semiconductor device having a semiconductor region extending in a first direction from a source or drain region and a gate structure extending in a second direction over the semiconductor region. The source or drain region has a width along the first direction that is greater than 50 nm and includes a first epitaxial region on at least a portion of the semiconductor region and a second epitaxial region on the first epitaxial region. Each of the first epitaxial region and second epitaxial region includes one or more n-type dopants or one or more p-type dopants.

According to an embodiment, an electronic device includes a chip package having one or more dies. At least one of the one or more dies includes a plurality of semiconductor nanoribbons extending in a first direction from a source or drain region, a gate structure extending in a second direction over the plurality of semiconductor nanoribbons, and a backside contact extending through a bottom surface of the source or drain region. The source or drain region has a width along the first direction that is greater than 50 nm and includes a first epitaxial region on at least a portion of the plurality of semiconductor nanoribbons and a second epitaxial region on the first epitaxial region. Each of the first epitaxial region and second epitaxial region includes one or more n-type dopants or one or more p-type dopants.

According to another embodiment, an integrated circuit includes a first semiconductor device having a first semiconductor region extending in a first direction from a first source or drain region and a first gate structure extending in a second direction over the first semiconductor region, and a second semiconductor device having a second semiconductor region extending in the first direction from a second source or drain region and a second gate structure extending in a second direction over the second semiconductor region. The second source or drain region has a width that is at least twice as large as a width of the first source or drain region along the first direction. The second source or drain region includes a first epitaxial region on at least a portion of the second semiconductor region and a second epitaxial region on the first epitaxial region. Each of the first epitaxial region and second epitaxial region includes one or more n-type dopants or one or more p-type dopants.

According to an embodiment, a method of forming an integrated circuit includes: forming a first fin and a second fin each comprising semiconductor material, the first and second fins extending above a substrate; forming sacrificial gates and spacer structures over the first and second fins; removing portions of the first and second fins not covered by the sacrificial gates and spacer structures; forming a first epitaxial region at exposed ends of the semiconductor material of the first fin and a second epitaxial region at exposed ends of the semiconductor material of the second fin; forming a dielectric liner on the top surface of the first epitaxial region and the second epitaxial region; removing the dielectric liner from the top surface of the second epitaxial region; forming a third epitaxial region on the second epitaxial region after removing the dielectric liner from the top surface of the second epitaxial region; and removing the dielectric liner from the top surface of the first epitaxial region.

The techniques can be used with any type of non-planar transistors, including finFETs (sometimes called double-gate transistors, or tri-gate transistors), or nanowire and nanoribbon transistors (sometimes called gate-all-around transistors), or forksheet transistors, to name a few examples. The source and drain regions can be, for example, epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide, indium phosphide).

Use of the techniques and structures provided herein may be detectable using tools such as electron microscopy including scanning/transmission electron microscopy (SEM/TEM), electron energy loss spectroscopy, scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In some embodiments, such tools may indicate the presence of multiple epitaxial regions within a given source or drain region. For example, a seam may be visible between epitaxial regions, with each region having one or more epitaxial layers with one or more n-type or one or more p-type dopants. In some embodiments, such tools may indicate the presence of a backside contact extending through multiple such epitaxial layers of a given source or drain region, however, the backside contact does not punch through the entire thickness of the source or drain region.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

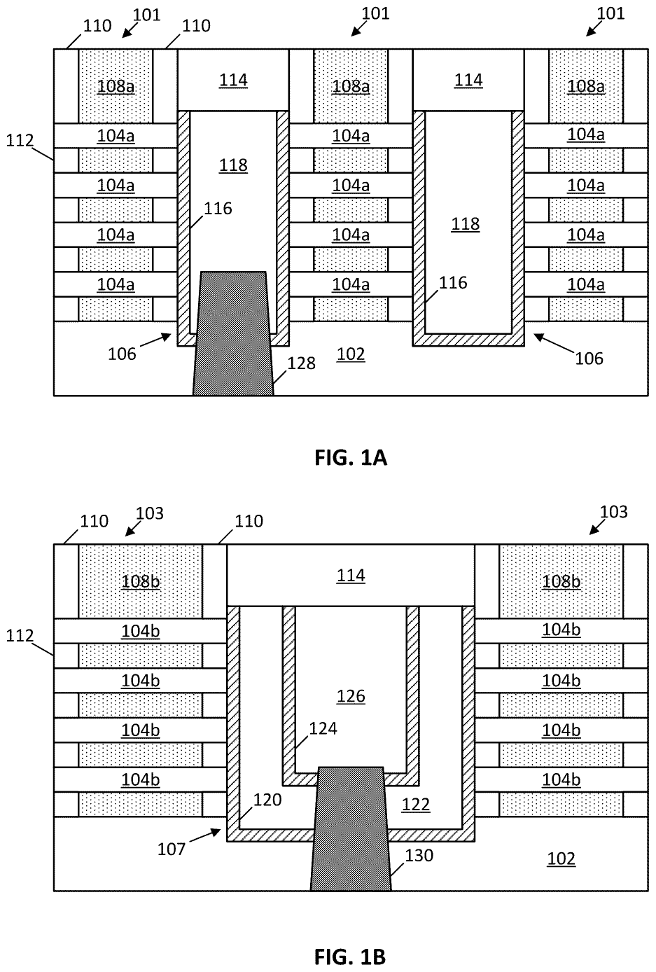

FIG. 1A is a cross-section view taken through semiconductor devices 101 along a ‘fin’ direction that illustrates the semiconductor bodies extending between source or drain regions of each of the semiconductor devices, in accordance with an embodiment of the present disclosure. FIG. 1B illustrates a cross-section view taken through different semiconductor devices 103 on the same die as semiconductor devices 101. Semiconductor devices 103 may be further along the same fin as semiconductor devices 101 or may be part of a different fin extending parallel to the fin of semiconductor devices 101. Each of the semiconductor devices may be, for instance, non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions). Other examples may have a forksheet structure having a p-type device and an n-type device separated by a dielectric spine or structure.

According to some embodiments, semiconductor devices 103 have wider gates compared to semiconductor devices 101. In an example, semiconductor devices 103 may be AMS devices while semiconductor devices may be logic or memory devices.

The semiconductor material used in each of the semiconductor devices may be formed from or on a semiconductor substrate. According to some embodiments, the substrate is removed following the completion of all topside processing and is replaced with a base dielectric structure 102. Base dielectric structure 102 may represent any number of dielectric layers and/or materials. In some examples, base dielectric structure 102 includes one or more layers of silicon dioxide.

The one or more semiconductor regions of the devices may include fins that can be, for example, native to the substrate (formed from the substrate itself), such as silicon fins etched from a bulk silicon substrate. Alternatively, the fins can be formed of material deposited onto the substrate. In one such example case, a blanket layer of SiGe can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. Again, the alternating layers can be blanket deposited and then etched into fins or deposited into fin-shaped trenches, in some examples.

Each semiconductor device 101 includes one or more semiconductor regions (also called channel regions), such as one or more nanoribbons 104a extending between epitaxial source or drain regions 106 in the first direction. Similarly, each semiconductor device 103 includes one or more semiconductor nanoribbons 104b extending between epitaxial source or drain regions 107 in the first direction. A given device channel region may include a combination of channel geometries (e.g., both nanowire and nanoribbon geometries within the same device channel region). First gate structures 108a extend over nanoribbons 104a of semiconductor devices 101 in a second direction (e.g., into and out of the page) to form the transistor gates of semiconductor devices 101, and second gate structures 108b extend over nanoribbons 104b of semiconductor devices 103 in the second direction to form the transistor gates of semiconductor devices 103. As noted above, second gate structures 108b are wider compared to first gate structures 108a along the first direction. Furthermore, source or drain region 107 is wider along the first direction compared to source or drain region 106. In some examples, source or drain region 107 has a total width of at least 50 nm along the first direction, or a width between about 50 nm and about 60 nm. Source or drain region 106 may have a total width along the first direction between about 20 nm and about 40 nm. In some examples, the width of source or drain region 107 is at least 1.5 times, at least 2 times, at least 2.5 times, or at least 3 times wider compared to the width of source or drain region 106.

Any of source or drain regions 106/107 may act as either a source region or a drain region, depending on the application and dopant profile. Any semiconductor materials suitable for source and drain regions can be used (e.g., group IV and group III-V semiconductor materials) for any of the illustrated source or drains regions 106/107. In any such cases, the overall doping profile of source or drain regions 106 and 107 may be different in part due to the difference in geometry between source or drain regions 106 and 107, as will be discussed in more detail herein. Semiconductor devices 101 and 103 may be n-channel devices having silicon (Si) with a concentration of one or more n-type dopants in the associated source or drain regions 106 and 107, or semiconductor devices 101 and 103 may be p-channel devices having silicon germanium (SiGe) with a concentration of one or more p-type dopants in the associated source or drain regions 106 and 107. Example p-type dopants include boron or aluminum, and example n-type dopants include phosphorous or arsenic.

The gate structures 108a/108b may each include a gate electrode that is made up of a conductive fill and one or more metal workfunction layers, according to some embodiments. The gate structures 108a/108b also include a gate dielectric that may represent any number of dielectric layers. The conductive fill may include any sufficiently conductive material such as a metal, metal alloy, or doped polysilicon. In some examples, the conductive fill includes tungsten (W), although other metals or conductive materials may be used, such as aluminum (Al), molybdenum (Mo), ruthenium (Ru), cobalt (Co), or doped polysilicon. Semiconductor devices 101 and 103 may be n-channel devices having gate structures 108a/108b with one or more workfunction layers of titanium aluminum carbide. Other metal workfunction layers of n-channel devices can include tantalum nitride (TaN). In some embodiments, semiconductor devices 101 and 103 are p-channel devices having gate structures 108a/108b with one or more workfunction layers of tungsten. Other metal workfunction layers of p-channel devices can include tantalum nitride (TaN) and titanium nitride (TiN).

The gate dielectric of each gate structure 108a/108b may include any suitable gate dielectric material(s). In some embodiments, the gate dielectric includes a layer of native oxide material (e.g., silicon dioxide germanium dioxide, or SiGe oxide) on nanoribbons 104a/104b, and a layer of high-k dielectric material (e.g., hafnium oxide or aluminum oxide) on the native oxide. According to some embodiments, spacer structures 110 and inner spacers 112 are present along the sidewalls of gate structures 108a/108b. Spacer structures 110 and inner spacers 112 may be any suitable dielectric material, such as silicon nitride, and provide separation between a given gate structure 108a/108b and the adjacent source or drain region 106/107. Inner spacers 112 may separate adjacent nanoribbons 104a/104b from one another along a third direction (e.g., a vertical direction).

According to some embodiments, a dielectric fill 114 is provided over source or drain regions 106 and 107. Dielectric fill 114 may be used to fill any remaining portion of the source/drain trenches that include source or drain regions 106 and 107 and that extend in the second direction (e.g., into and out of the page). Accordingly, dielectric fill 114 may extend over the top surfaces of source or drain regions 106 and 107 and may also extend over side surfaces of source or drain regions 106 and 107 (e.g., between source or drain regions along the second direction). In some embodiments, one or more topside conductive contacts extend through dielectric fill 114 to contact at least a portion of the top surface of a given source or drain region 106 or 107. The topside conductive contacts may also extend into at least a portion of the given source or drain region 106 or 107.

According to some embodiments, source or drain region 106 includes an epitaxial region made up of one or more epitaxial layers. For example, a first epitaxial layer 116 may be grown from the ends of nanoribbons 104a (and possibly from the semiconductor substrate before it is removed) while a second epitaxial layer 118 may be grown on first epitaxial layer 116. According to some embodiments, first epitaxial layer 116 includes undoped Si (n-type) or undoped SiGe (p-type), and second epitaxial layer 118 includes Si doped with phosphorus or arsenic (n-type), or SiGe doped with boron (p-type). First epitaxial layer 116 may have a thickness of less than 15 nm, less than 10 nm, or less than 5 nm. In some embodiments, first epitaxial layer 116 and second epitaxial layer 118 are formed at separate times, such that there is a clear step discontinuity in the doping concentration between zero dopant concentration in first epitaxial layer 116 and the doping concentration found in second epitaxial layer 118. In some embodiments, a dopant concentration gradient exists across the boundary between first epitaxial layer 116 and second epitaxial layer 118, such that the doping concentration gradually increases from zero dopant concentration in first epitaxial layer 116 to the dopant concentration within second epitaxial layer 118.

According to some embodiments, source or drain region 107 includes more than one epitaxial region, with each region made up of one or more epitaxial layers. In the illustrated example, a first epitaxial region includes a third epitaxial layer 120 and a fourth epitaxial layer 122 on third epitaxial layer 120. According to some embodiments, third epitaxial layer 120 is formed at the same time as first epitaxial layer 116, and thus has substantially the same properties as first epitaxial layer 116. Furthermore, fourth epitaxial layer 122 may be formed at the same time as second epitaxial layer 118, and thus has substantially the same properties as second epitaxial layer 118. According to some embodiments, source or drain region 107 includes a second epitaxial region that includes a fifth epitaxial layer 124 on fourth epitaxial layer 122, and a sixth epitaxial layer 126 on fifth epitaxial layer 124. In some examples, fifth epitaxial layer 124 includes undoped Si (n-type) or undoped SiGe (p-type), and sixth epitaxial layer 126 includes Si doped with phosphorus or arsenic (n-type), or SiGe doped with boron (p-type). Accordingly, fifth epitaxial layer 124 may be substantially similar to third epitaxial layer 120 and sixth epitaxial layer 126 may be substantially similar to fourth epitaxial layer 122. In some embodiments, a visible seam is present between the first epitaxial region and the second epitaxial region (e.g., at the boundary between fourth epitaxial layer 122 and fifth epitaxial layer 124.

The inclusion of the second epitaxial region (e.g., having fifth epitaxial layer 124 and sixth epitaxial layer 126) effectively increases the volume of source or drain region 107 and prevents a contact from punching through a thickness of the region in long-channel devices like semiconductor devices 103. Any number of backside contacts may be provided to contact any number of source or drain regions from below. For example, a first backside contact 128 may be provided to make contact with source or drain region 106 from below and a second backside contact 130 may be provided to make contact with source or drain region 107 from below. According to some embodiments, each of backside contact 128 and 130 extends through at least a portion of base dielectric structure 102 and through at least a portion of source or drain region 106 and source or drain region 107, respectively. In the illustrated example, second backside contact 130 extends through an entire thickness of each of at least third epitaxial layer 120 and fourth epitaxial layer 122. Either or both of first backside contact 128 and second backside contact 130 may provide a conductive pathway between their respective source or drain region 106 or 107 and a buried conductive line that acts as a power or ground rail. Backside contacts 128 and 130 may include any suitable conductive material, such as tungsten, cobalt, ruthenium, or molybdenum.

### Fabrication Methodology

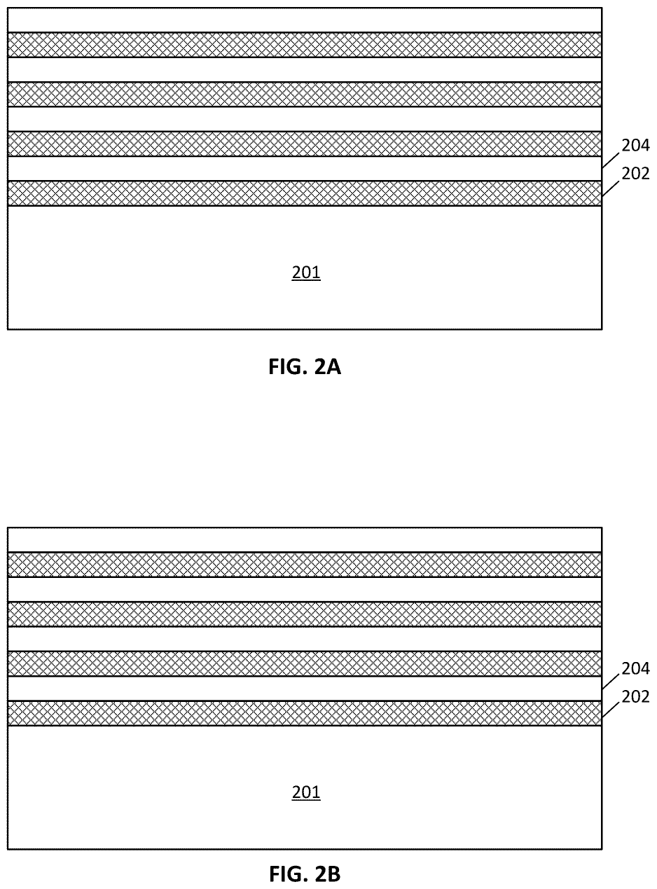

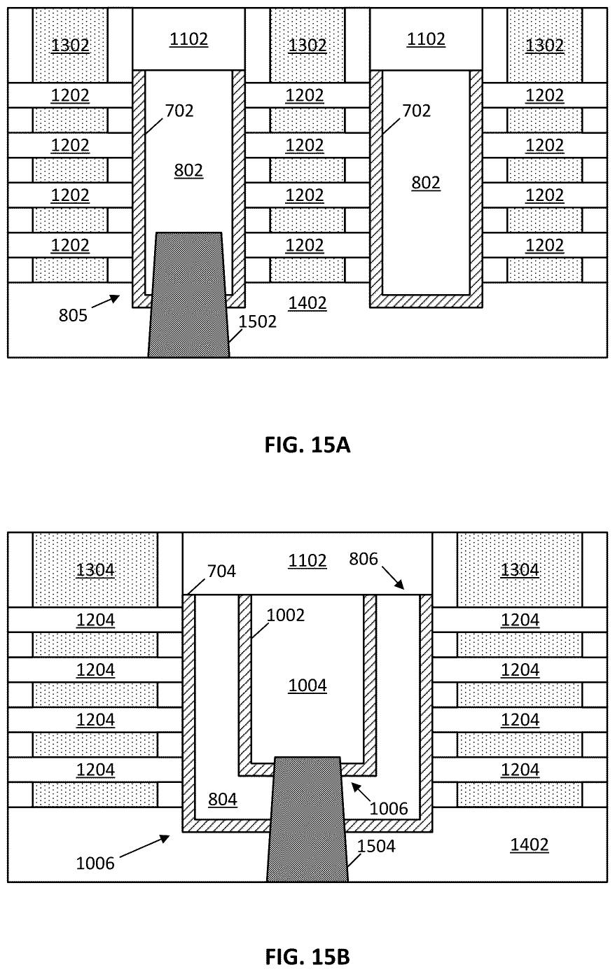

FIGS. 2A-15A and 2B-15B include cross-sectional views that collectively illustrate an example process for forming an integrated circuit having different semiconductor devices with different source/drain widths and different epitaxial growth profiles, in accordance with an embodiment of the present disclosure. FIG. 2A-15A represent a similar cross-sectional view as that of FIG. 1A across a series of semiconductor devices 101, while FIGS. 2B-15B represent a similar cross-sectional view as that of FIG. 1B across a series of semiconductor devices 103. Each set of figures sharing the same letter shows an example structure that results from the process flow up to that point in time, so the depicted structure evolves as the process flow continues, culminating in the structure shown in FIGS. 15A and 15B, which is similar to the structure shown in FIGS. 1A and 1B. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but other materials and process parameters may be used as well, as will be appreciated in light of this disclosure.

FIGS. 2A and 2B each illustrates a cross-sectional view taken through a substrate 201 having a series of material layers formed over substrate 201, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201.

Substrate 201 can be, for example, a bulk substrate including group IV semiconductor material (such as silicon, germanium, or SiGe), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires, nanoribbons, and/or nanosheets (e.g., alternating layers of silicon and SiGe, or alternating layers indium gallium arsenide and indium phosphide). Any number of substrates can be used, and a given die may include any combination of nanowires (e.g., circular or square cross-section), nanoribbons (e.g., ribbon-like cross-section), and nanosheets (e.g., sheet-like cross-section).

According to some embodiments, semiconductor layers 204 have a different material composition than sacrificial layers 202. In some embodiments, semiconductor layers 204 include a semiconductor material suitable for use as a nanoribbon such as silicon (Si), SiGe, germanium, or III-V materials like indium phosphide (InP) or gallium arsenide (GaAs). Sacrificial layers 202 include a material that can be selectively removed relative to semiconductor layers 204. In some examples, for instance, semiconductor layers 204 are silicon and sacrificial layers 202 are SiGe, or vice-versa. In some other examples where SiGe is used in each of semiconductor layers 204 and in sacrificial layers 202, the germanium concentration is different between semiconductor layers 204 and sacrificial layers 202, so as to allow for etch selectivity. For example, semiconductor layers 204 may include a higher germanium content compared to sacrificial layers 202.

While dimensions can vary from one example embodiment to the next, the thickness of each semiconductor layer 204 may be between about 5 nm and about 20 nm, in some examples. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any material deposition technique, such as chemical vapor deposition (CVD), plasma-enhanced chemical vapor deposition (PECVD), physical vapor deposition (PVD), or atomic layer deposition (ALD), or epitaxial growth.

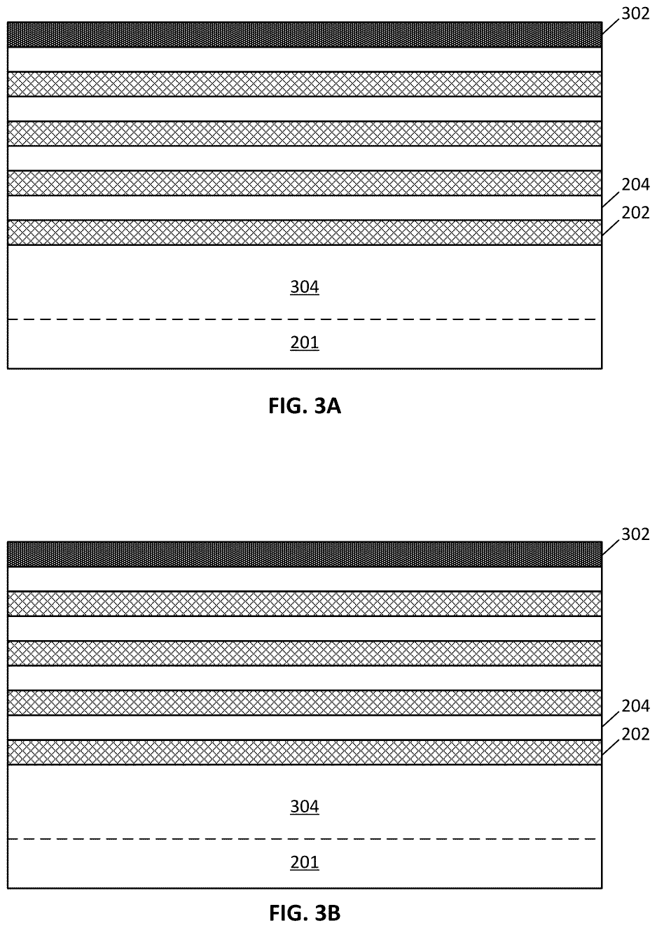

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. Cap layer 302 extends along the top of each fin in a first direction. In some embodiments, FIGS. 3A and 3B illustrate different portions of the same fin (e.g., patterned under the same strip of cap layer 302). In some embodiments, FIGS. 3A and 3B illustrate portions of different parallel fins (e.g., under different parallel strips of cap layer 302).

According to some embodiments, an anisotropic etching process through the layer stack continues into at least a portion of substrate 201. Portions of substrate 201 beneath the fins are not etched and yield subfin regions 304. The etched portions of substrate 201 that are not under the fins may be filled with a dielectric fill that acts as shallow trench isolation (STI) between adjacent fins. The dielectric fill is not shown in these cross-sections as it extends in the first direction along the sides of subfin regions 304 that are into and out of the page. The dielectric fill may be any suitable dielectric material such as silicon dioxide. The subfin regions 304 represent remaining portions of substrate 201 flanked by the dielectric fill, according to some embodiments.

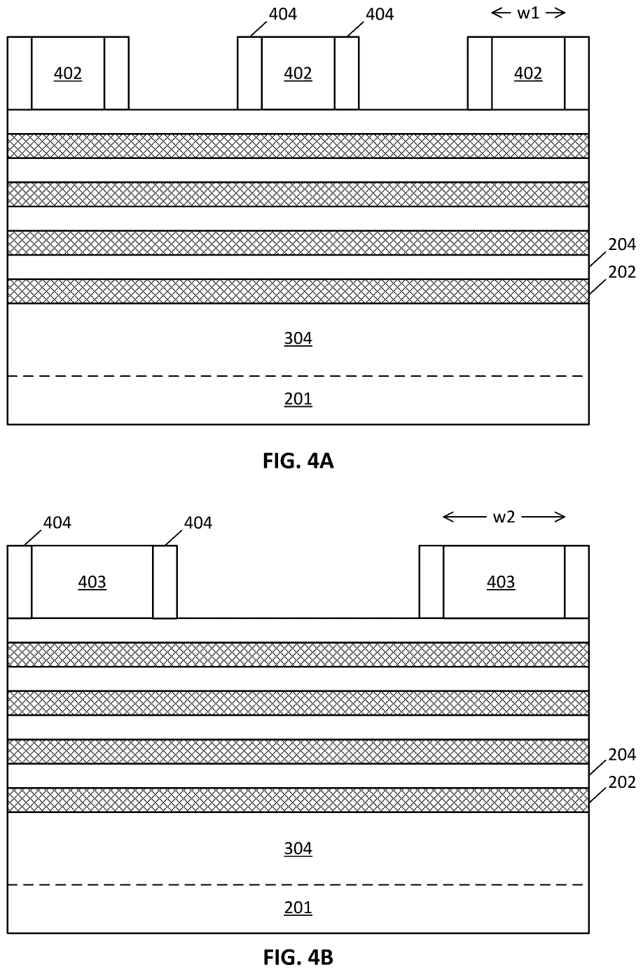

FIGS. 4A and 4B depict cross-section views of the structures shown in FIGS. 3A and 3B following the formation of sacrificial gates 402/403 and spacer structures 404, according to some embodiments. A gate masking layer may first be patterned in strips that extend orthogonally across each of the fins (e.g., in a second direction) in order to form corresponding sacrificial gates 402/403 in strips beneath the gate masking layers. Afterwards, the gate masking layers may be removed or may remain as a cap layer above each sacrificial gate 402/403. According to some embodiments, the sacrificial gate material is removed in all areas not protected by the gate masking layers. Sacrificial gates 402/403 may be any suitable material that can be selectively removed without damaging the semiconductor material of the fins. In some examples, sacrificial gates 402/403 includes polysilicon.

Sacrificial gates 402 may have a first width w1 along the first direction that is less than a second width w2 of sacrificial gates 403 along the first direction. In some examples, second width w2 is at least 15%, at least 25%, at least 30%, at least 40% or at least 50% greater than first width w1.

According to some embodiments, spacer structures 404 are formed along the sidewalls of sacrificial gates 402/403. Spacer structures 404 may be conformally deposited (e.g., CVD or ALD) and then etched back or otherwise removed (e.g., via anisotropic or directional etch) from horizontal surfaces, such that spacer structures 404 remain mostly only on sidewalls of any exposed structures. The width of spacer structures 404 (along the first direction) may vary from one example to the next, but in some cases is in the range of 3 nm to 20 nm. According to some embodiments, spacer structures 404 may be any suitable dielectric material, such as silicon nitride, silicon carbon nitride, or silicon oxycarbonitride. In one such embodiment, spacer structures 404 comprise a nitride and the dielectric fill adjacent to subfin regions 304 comprises an oxide, so as to provide a degree of etch selectivity during final gate processing.

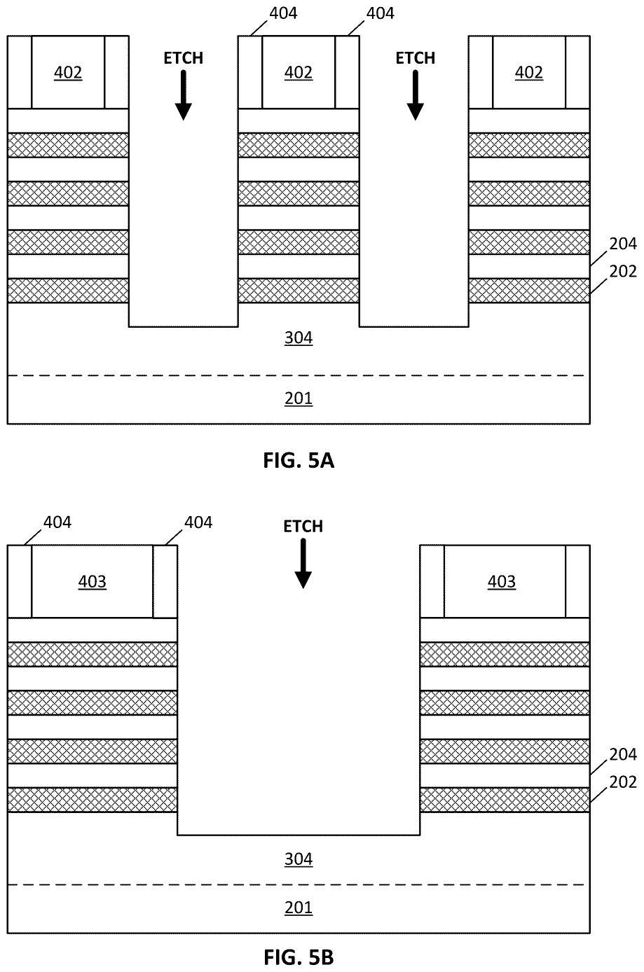

FIGS. 5A and 5B depict cross-section views of the structures shown in FIGS. 4A and 4B following the removal of exposed portions of the fins not protected by sacrificial gates 402/403 and spacer structures 404, according to some embodiments. The exposed fin portions may be removed using any anisotropic etching process, such as reactive ion etching (RIE) or other directional etch process. The removal of the exposed fin portions creates source or drain trenches that alternate with gate trenches (currently filled with sacrificial gates 402/403) along the first direction, according to some embodiments. In some embodiments, at least a portion of subfin regions 304 is also removed such that a top surface of subfin regions 304 is recessed below a top surface of the adjacent dielectric fill.

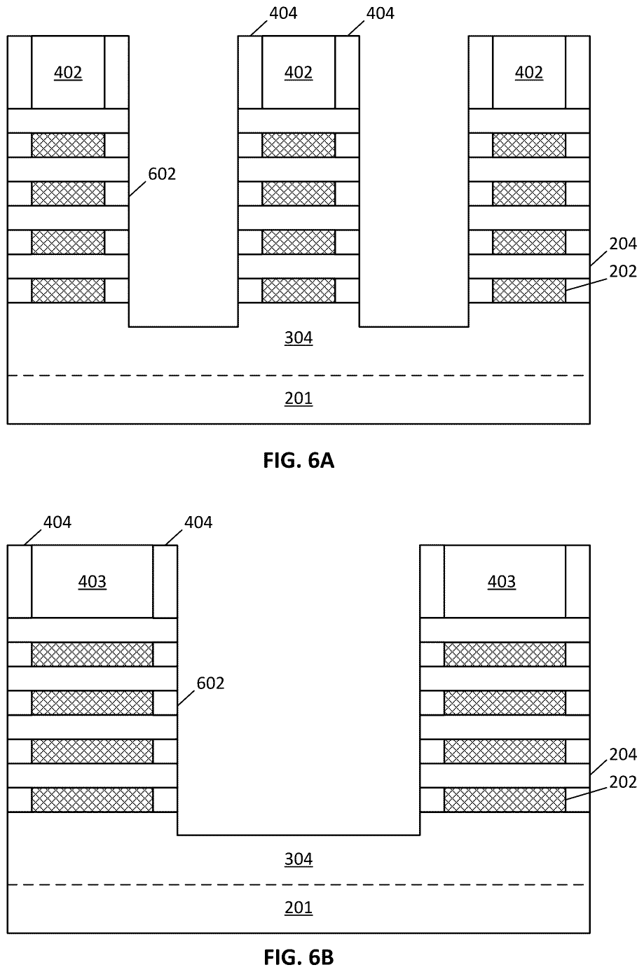

FIGS. 6A and 6B depict cross-section views of the structures shown in FIGS. 5A and 5B following the removal of portions of sacrificial layers 202 and formation of inner spacers 602 within the lateral recesses, according to some embodiments. An isotropic etching process may be used to selectively recess the exposed ends of each sacrificial layer 202 (e.g., while etching comparatively little of semiconductor layers 204).

Inner spacers 602 may have a material composition that is similar to or the exact same as spacer structures 404. Accordingly, inner spacers 602 may be any suitable dielectric material that exhibits high etch selectively to semiconductor materials such as silicon and/or silicon germanium. Inner spacers 602 may be, for example, conformally deposited over the sides of the fin structure using a conformal deposition process like CVD or ALD and then etched back using an isotropic etching process to expose the ends of semiconductor layers 204. According to some embodiments, inner spacers 602 have a similar width (e.g., along the first direction) to spacer structures 404.

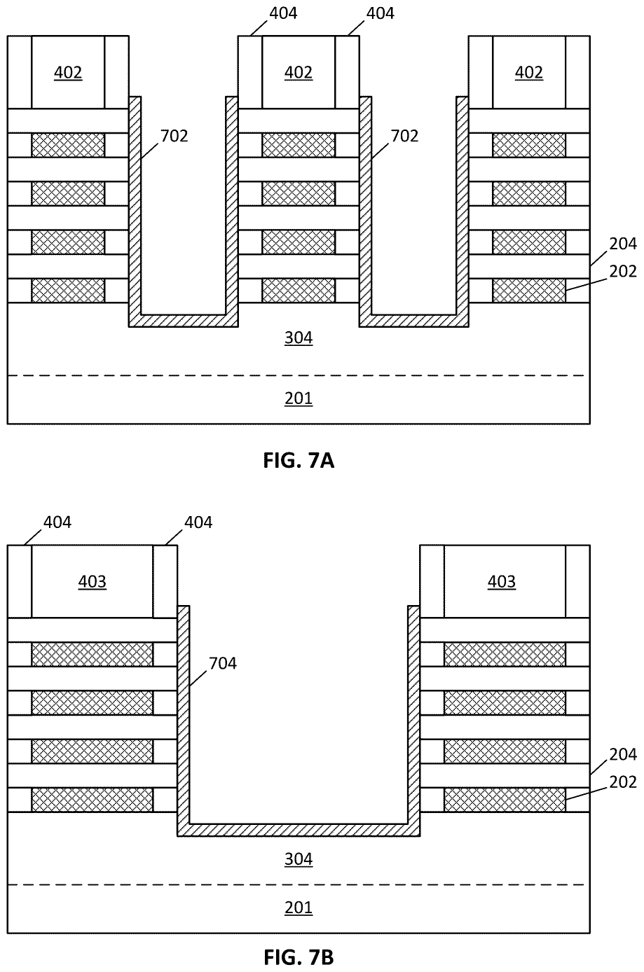

FIGS. 7A and 7B depict cross-section views of the structure shown in FIGS. 6A and 6B, respectively, following the formation of a first epitaxial layer 702 within the source/drain trenches of the devices of FIG. 7A and a second epitaxial layer 704 within the source/drain trenches of the devices of FIG. 7B, according to some embodiments. First epitaxial layer 702 and second epitaxial layer 704 may be grown at substantially the same time from the exposed ends of semiconductor layers 204 and any exposed portion of subfin 304. According to some embodiments, first epitaxial layer 702 and second epitaxial layer 704 are each undoped semiconductor material, such as undoped Si for n-type devices or undoped SiGe for p-type devices. It should be noted that the material of first epitaxial layer 702 and second epitaxial layer 704 is grown from exposed semiconductor surfaces in the source/drain trenches, and that the growth may merge together to form the continuous layers over the sidewalls and bottom surfaces of the source/drain trenches. Discontinuities may exist in first epitaxial layer 702 and second epitaxial layer 704 due to the growth process.

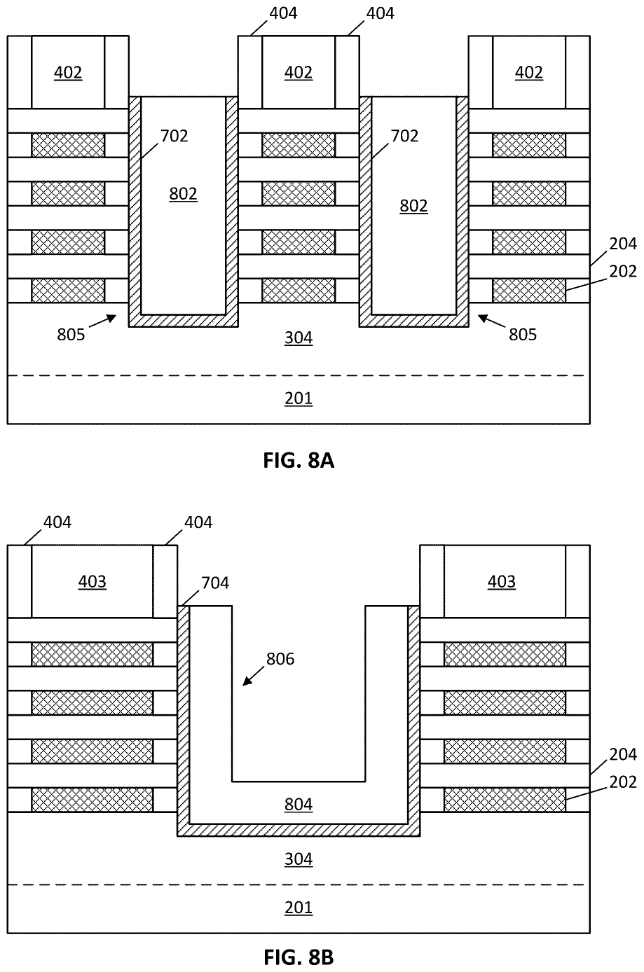

FIGS. 8A and 8B depict cross-section views of the structure shown in FIGS. 7A and 7B, respectively, following the formation of a third epitaxial layer 802 on first epitaxial layer 702 within the source/drain trenches of the devices of FIG. 8A and a fourth epitaxial layer 804 on second epitaxial layer 704 within the source/drain trenches of the devices of FIG. 8B, according to some embodiments. Third epitaxial layer 802 and fourth epitaxial layer 804 may be grown at substantially the same time from the exposed surfaces of first epitaxial layer 702 and second epitaxial layer 704, respectively. According to some embodiments, third epitaxial layer 802 and fourth epitaxial layer 804 are each doped semiconductor material, such as Si doped with phosphorous or arsenic for n-type devices or SiGe doped with boron for p-type devices.

In some embodiments, first epitaxial layer 702 and third epitaxial layer 802 are formed at separate times, such that there is a clear step discontinuity in the doping concentration between zero dopant concentration in first epitaxial layer 702 and the doping concentration found in third epitaxial layer 802. In some embodiments, a dopant concentration gradient exists across the boundary between first epitaxial layer 702 and third epitaxial layer 802, such that the doping concentration gradually increases from zero dopant concentration in first epitaxial layer 702 to the dopant concentration within third epitaxial layer 802. Whichever dopant scheme is used, the same dopant scheme will also be observed across second epitaxial layer 704 and fourth epitaxial layer 804, according to some embodiments.

The growth of first epitaxial layer 702 and third epitaxial layer 802 completes the formation of first source or drain regions 805 of the devices in FIG. 8A, however, second epitaxial layer 704 and fourth epitaxial layer 804 provide only a first epitaxial region 806 of second source or drain regions of the devices in FIG. 8B. The remainder of the source/drain trench outside of first epitaxial region 806 is devoid of any material, according to some embodiments. In this example, first epitaxial region 806 includes both second epitaxial layer 704 and fourth epitaxial layer 804.

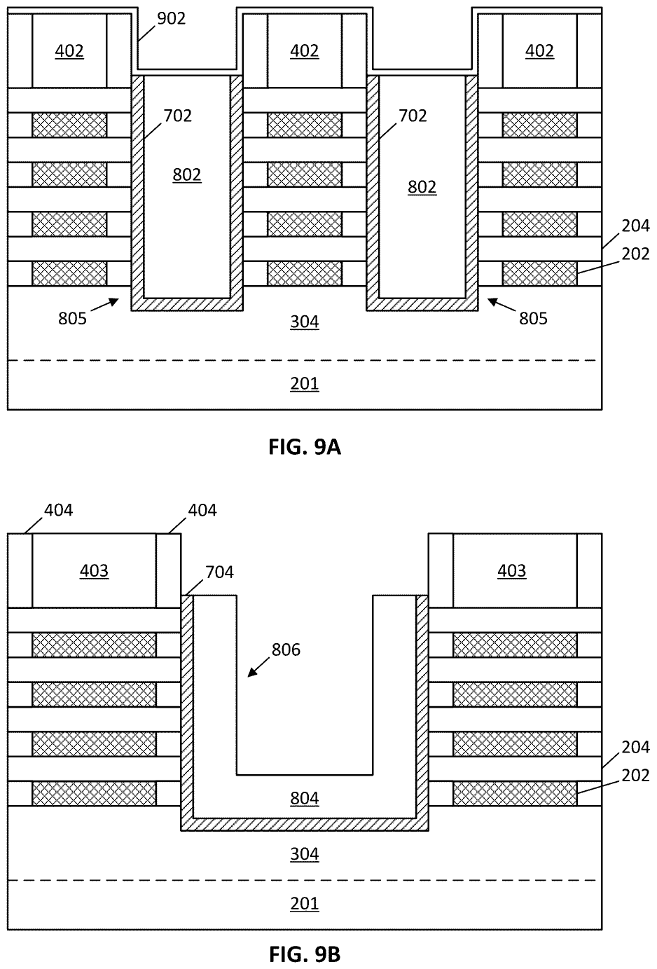

FIGS. 9A and 9B depict cross-section views of the structure shown in FIGS. 8A and 8B, respectively, following the formation of a liner 902, according to some embodiments. Liner 902 may be any suitable dielectric material, such as silicon dioxide. In some examples, liner 902 includes any dielectric material having sufficient etch selectivity with spacer structures 404 so as to reduce the damage to spacer structure 404 during the removal of liner 902.

According to some embodiments, liner 902 is deposited using any suitable conformal deposition technique, such as CVD, PECVD, or ALD. Liner 902 may be deposited over all exposed surfaces and subsequently patterned using suitable lithography techniques to remove the liner from first epitaxial region 806 while keeping liner 902 on the top surfaces of source or drain regions 805. Liner 902 may have a thickness between about 2 nm and about 5 nm, or have a thickness up to 10 nm.

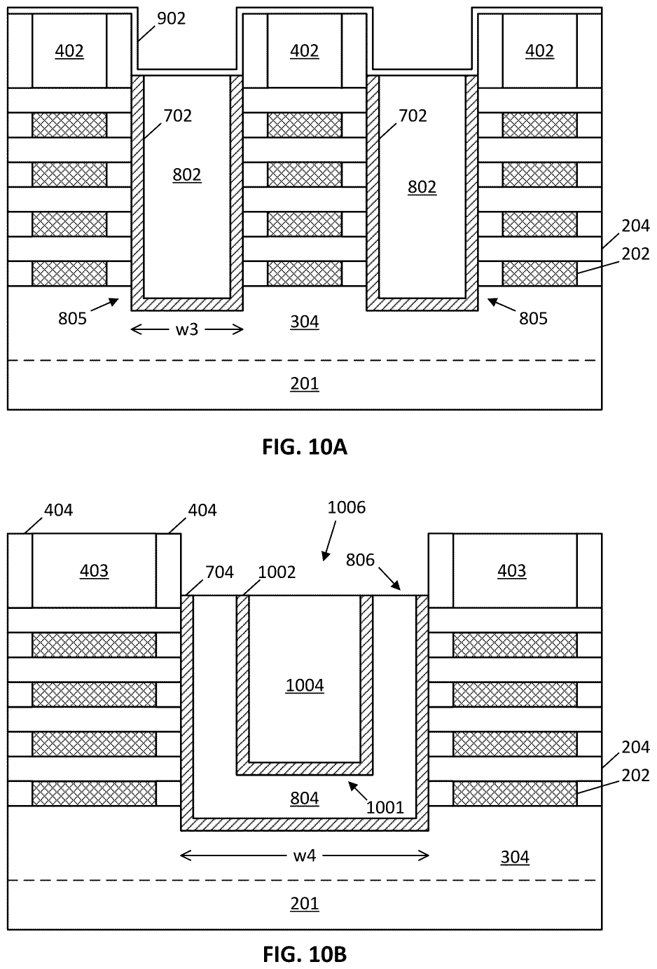

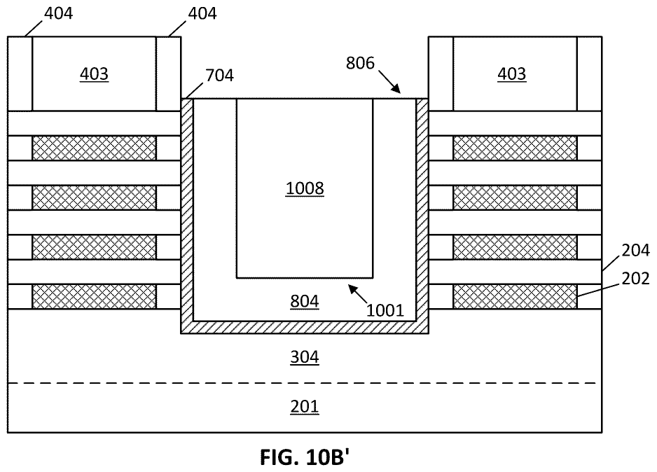

FIGS. 10A and 10B depict cross-section views of the structure shown in FIGS. 9A and 9B, respectively, following the formation of a second epitaxial region 1001 on first epitaxial region 806, according to some embodiments. One or more additional epitaxial layers may be grown within the source/drain trench of the devices shown in FIG. 10B with liner 902 protecting source or drain regions 805 from any further material growth.

In the illustrated example, a fifth epitaxial layer 1002 is grown on fourth epitaxial layer 804, and a sixth epitaxial layer 1004 is grown on fifth epitaxial layer 1002. According to some embodiments, fifth epitaxial layer 1002 is substantially similar to second epitaxial layer 704 and sixth epitaxial layer 1004 is substantially similar to fourth epitaxial layer 804. As such, fifth epitaxial layer 1002 may include a substantially undoped semiconductor material (e.g., Si or SiGe), and sixth epitaxial layer 1004 may include a doped semiconductor material (e.g., having the same one or more dopants as fourth epitaxial layer 804). In some examples, fourth epitaxial layer 804 and sixth epitaxial layer 1004 have the same dopant concentration of either n-type or p-type dopant.

Since there are one or more other fabrication operations performed between the formation of fourth epitaxial layer 804 and the formation of fifth epitaxial layer 1002, an observable seam is present along the boundary between fourth epitaxial layer 804 and fifth epitaxial layer 1002, according to some embodiments. The dopant scheme between fifth epitaxial layer 1002 and sixth epitaxial layer 1004 may be similar to that described above between second epitaxial layer 704 and fourth epitaxial layer 804 (e.g., step discontinuity or gradient doping across the boundary between fifth epitaxial layer 1002 and sixth epitaxial layer 1004).

According to some embodiments, the formation of second epitaxial region 1001 completes the formation of source or drain region 1006. Due to the geometry of the source/drain trenches, source or drain region 805 has a smaller width w3 compared to the width w4 of source or drain region 1006. For example, source or drain region 1006 may have a width w4 that is at least 1.5 times, at least 2 times, at least 2.5 times, or at least 3 times greater than width w3 of source or drain region 805. In some examples, width w4 is at least 50 nm or is between 50 nm and 60 nm.

Second epitaxial region 1001 may include a different arrangement of epitaxial layers. FIG. 10B′ illustrates another embodiment where second epitaxial region 1001 includes a single epitaxial layer 1008 grown on fourth epitaxial layer 804. Epitaxial layer 1008 may have a similar material composition as fourth epitaxial layer 804. Accordingly, epitaxial layer 1008 may be a doped semiconductor material to match fourth epitaxial layer 804.

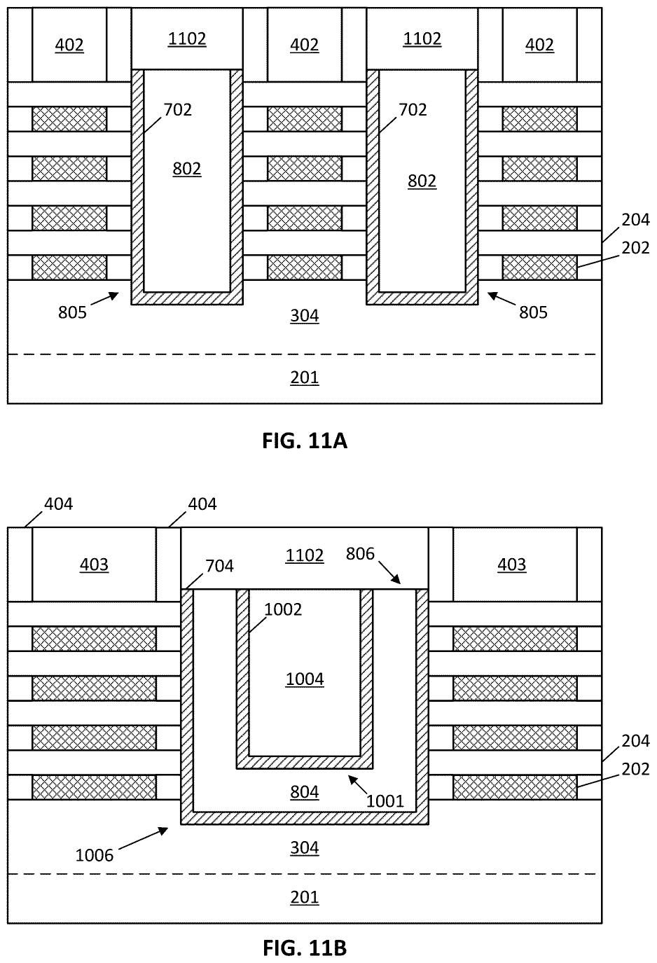

FIGS. 11A and 11B depict cross-section views of the structure shown in FIGS. 10A and 10B, respectively, following the formation of a dielectric fill 1102 over source or drain regions 805 and 1006. In some examples, dielectric fill 1102 occupies a remaining volume within the source/drain trenches around and over portions of source or drain regions 805 and 1006. Dielectric fill 1102 may be any suitable dielectric material, such as silicon dioxide. In some examples, dielectric fill 1102 extends up to and planar with a top surface of spacer structures 404 (e.g., following a polishing procedure). One or more topside conductive contacts may be formed through dielectric fill 1102 to contact a top surface of any of source or drain regions 805/1006.

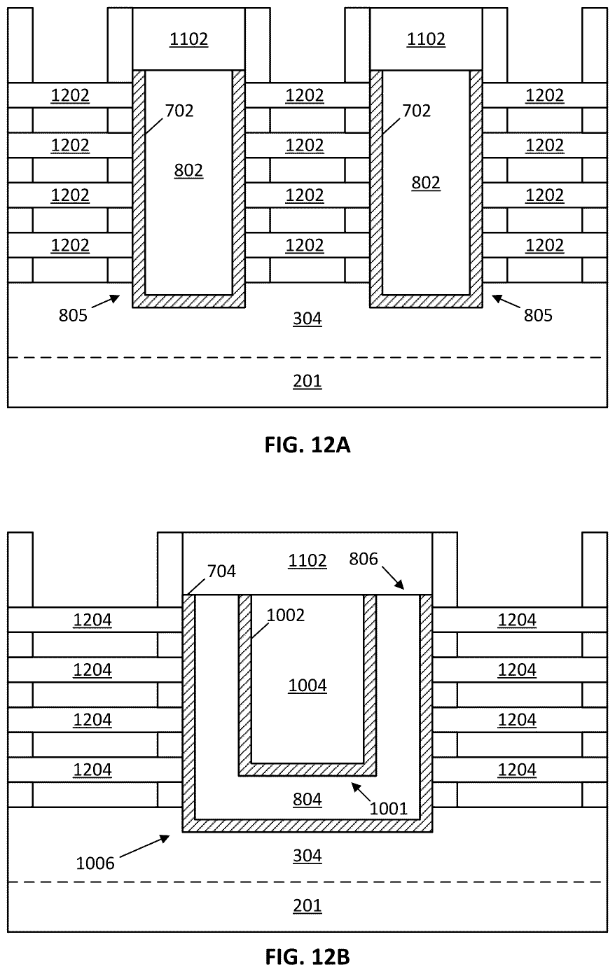

FIGS. 12A and 12B depict cross-section views of the structure shown in FIGS. 11A and 11B, respectively, following the removal of sacrificial gates 402 and sacrificial layers 202, according to some embodiments. In examples where gate masking layers are still present, they may be removed at this time. Once sacrificial gates 402 are removed, the remaining fin portions extending between spacer structures 404 are exposed.

In the example where the fins include alternating sacrificial layers 202 and semiconductor layers 204, sacrificial layers 202 are selectively removed to leave behind nanoribbons 1202 extending between source or drain regions 805 and nanoribbons 1204 extending between source or drain regions 1006. Each vertical set of nanoribbons 1202/1204 represents the semiconductor region (also called channel region) of a different semiconductor device. It should be understood that any of nanoribbons 1202/1204 may also be nanowires or nanosheets (e.g., all 1202 may be nanowires and all 1204 may be nanoribbons, or vice-versa, or all 1202 and 1204 may be nanowires, nanoribbons, or nanosheets, or some of 1202 may be nanowires and others of 1202 may be nanoribbons and/or or some of 1204 may be nanowires and others of 1204 may be nanoribbons). Channel sculpting techniques can be used to provide desired channel geometry and diversity, such as the example case where some but not all of nanoribbons 1202 and/or 1204 in a given channel region are formed by thinning nanowires so they are more ribbon-like while others in that same channel region are left as nanowires. More generally, channel sculpting can provide any number of diverse channel configurations. Sacrificial gates 402 and sacrificial layers 202 may be removed using the same isotropic etching process or different isotropic etching processes. Any channel sculpting can be carried out using isotropic and/or anisotropic etching processes configured to remove unmasked or otherwise exposed channel semiconductor material of 1202 and/or 1204 within the gate trench, until a desired channel configuration is achieved.

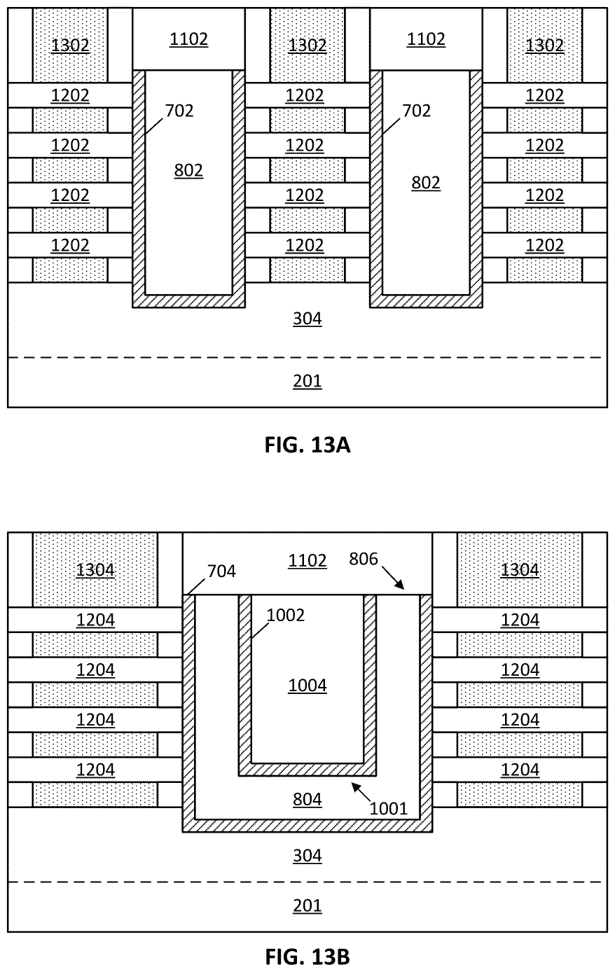

FIGS. 13A and 13B depict cross-section views of the structure shown in FIGS. 12A and 12B, respectively, following the formation of first gate structures 1302 around the suspended nanoribbons 1202 and second gate structures 1304 around the suspended nanoribbons 1204, according to an embodiment of the present disclosure. As noted above, gate structures 1302/1304 each include a gate dielectric and a gate electrode.

The gate dielectric may be conformally deposited around nanoribbons 1202/1204 using any suitable deposition process, such as ALD. The gate dielectric may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric is hafnium oxide with a thickness between about 1 nm and about 5 nm. In some embodiments, the gate dielectric may include one or more silicates (e.g., titanium silicate, tungsten silicate, niobium silicate, and silicates of other transition metals). The gate dielectric may be a multilayer structure, in some examples. For instance, the gate dielectric may include a first layer on nanoribbons 1202/1204, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on the gate dielectric to improve its quality when a high-k dielectric material is used. In some embodiments, the high-k material can be nitridized to improve its aging resistance.

The gate electrode may be deposited over the gate dielectric and can be any standard or proprietary conductive material that may include any number of gate cuts. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, one or more workfunction layers, resistance-reducing layers, and/or barrier layers. In an example, first gate structures 1302 and/or second gate structures 1304 include n-type workfunction materials such as, for example, titanium aluminum carbide or tantalum nitride. In an example, first gate structures 1302 and/or second gate structures 1304 include p-type workfunction materials such as tungsten.

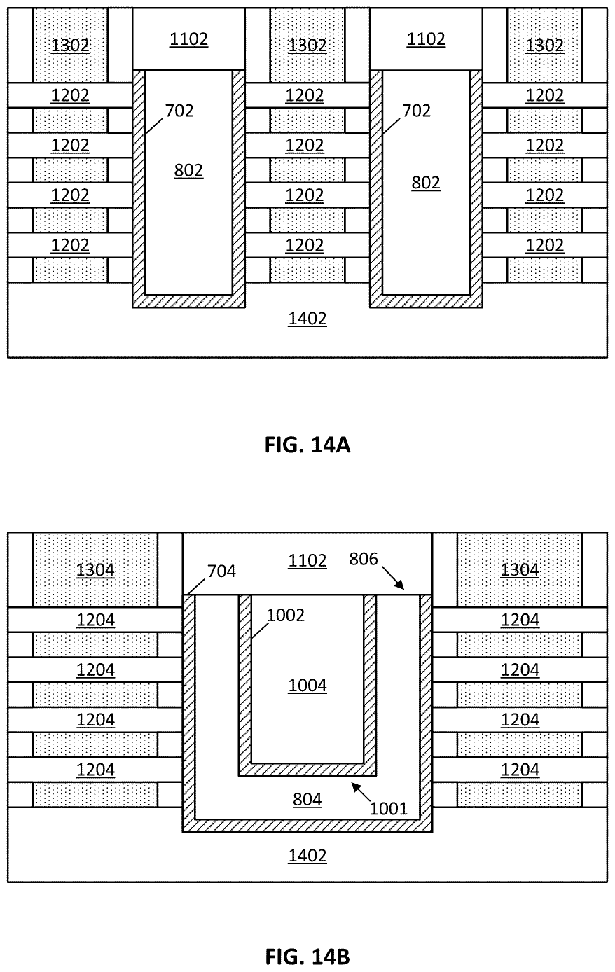

FIGS. 14A and 14B depict cross-section views of the structure shown in FIGS. 13A and 13B, respectively, following the removal of a backside portion of substrate 201, according to some embodiments. Any number of polishing, grinding, or etching processes (e.g., CMP) may be used to remove the bulk portion of substrate 201. According to some embodiments, substrate 201 is removed until a bottom surface of subfin regions 304 and/or the dielectric layer adjacent to the subfin regions 304 is exposed.

According to some embodiments, the exposed subfin regions 304 are removed and replaced with a base dielectric structure 1402. Subfin regions 304 may be removed using a suitable isotropic etching process followed by the backside formation of base dielectric structure 1402. According to some embodiments, base dielectric structure 1402 includes any number of dielectric layers. In some examples, base dielectric structure 1402 includes a layer of silicon dioxide. Base dielectric layer may have a polished bottom surface.

FIGS. 15A and 15B depict cross-section views of the structure shown in FIGS. 14A and 14B, respectively, following the formation of a backside contacts 1502 and 1504 within respective backside cavities, according to some embodiments. Backside contacts 1502 and 1504 may include any suitable conductive material, such as any of tungsten, ruthenium, molybdenum, or cobalt. Prior to the deposition of conductive material to form backside contacts 1502/1504, a directional etch (e.g., RIE) is performed to form backside cavities through a thickness of base dielectric structure 1402 and through at least a portion of respective source or drain regions 805 and 1006. As a result of the etching process, the backside cavities have a tapering profile with a width that decreases from the opening of the cavity (e.g., at the bottom surface of base dielectric structure 1402), according to some embodiments. Backside contacts 1502 and 1504 are formed by depositing conductive material within the backside cavities, and thus take on the tapering shape of the backside cavities. According to some embodiments, backside contact 1504 extends through at least an entire thickness of second epitaxial layer 704 and fourth epitaxial layer 804. In the illustrated example, backside contact 1504 extends into at least a portion of sixth epitaxial layer 1004. One or more additional backside interconnect layers may be formed beneath base dielectric structure 1402. In some embodiments, one of these layers includes a conductive power rail or ground rail that is conductively coupled to either or both backside contact 1502 and 1504.

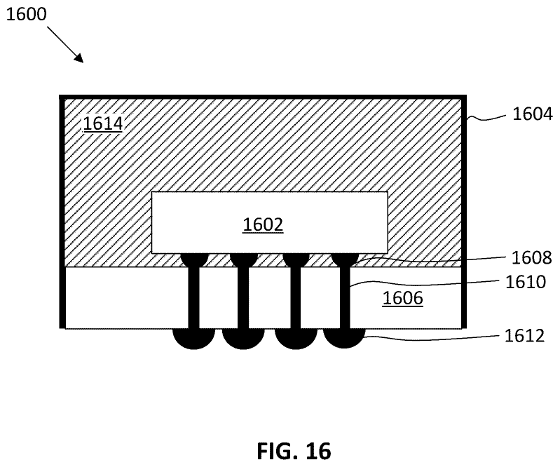

FIG. 16 illustrates an example embodiment of a chip package 1600, in accordance with an embodiment of the present disclosure. As can be seen, chip package 1600 includes one or more dies 1602. One or more dies 1602 may include at least one integrated circuit having semiconductor devices, such as any of the semiconductor devices disclosed herein. One or more dies 1602 may include any other circuitry used to interface with other devices formed on the dies, or other devices connected to chip package 1600, in some example configurations.

As can be further seen, chip package 1600 includes a housing 1604 that is bonded to a package substrate 1606. The housing 1604 may be any standard or proprietary housing, and may provide, for example, electromagnetic shielding and environmental protection for the components of chip package 1600. The one or more dies 1602 may be conductively coupled to a package substrate 1606 using connections 1608, which may be implemented with any number of standard or proprietary connection mechanisms, such as solder bumps, ball grid array (BGA), pins, or wire bonds, to name a few examples. Package substrate 1606 may be any standard or proprietary package substrate, but in some cases includes a dielectric material having conductive pathways (e.g., including conductive vias and lines) extending through the dielectric material between the faces of package substrate 1606, or between different locations on each face. In some embodiments, package substrate 1606 may have a thickness less than 1 millimeter (e.g., between 0.1 millimeters and 0.5 millimeters), although any number of package geometries can be used. Additional conductive contacts 1612 may be disposed at an opposite face of package substrate 1606 for conductively contacting, for instance, a printed circuit board (PCB). One or more vias 1610 extend through a thickness of package substrate 1606 to provide conductive pathways between one or more of connections 1608 to one or more of contacts 1612. Vias 1610 are illustrated as single straight columns through package substrate 1606 for ease of illustration, although other configurations can be used (e.g., damascene, dual damascene, through-silicon via, or an interconnect structure that meanders through the thickness of substrate 1606 to contact one or more intermediate locations therein). In still other embodiments, vias 1610 are fabricated by multiple smaller stacked vias, or are staggered at different locations across package substrate 1606. In the illustrated embodiment, contacts 1612 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1612, to inhibit shorting.

In some embodiments, a mold material 1614 may be disposed around the one or more dies 1602 included within housing 1604 (e.g., between dies 1602 and package substrate 1606 as an underfill material, as well as between dies 1602 and housing 1604 as an overfill material). Although the dimensions and qualities of the mold material 1614 can vary from one embodiment to the next, in some embodiments, a thickness of mold material 1614 is less than 1 millimeter. Example materials that may be used for mold material 1614 include epoxy mold materials, as suitable. In some cases, the mold material 1614 is thermally conductive, in addition to being electrically insulating.

### Methodology

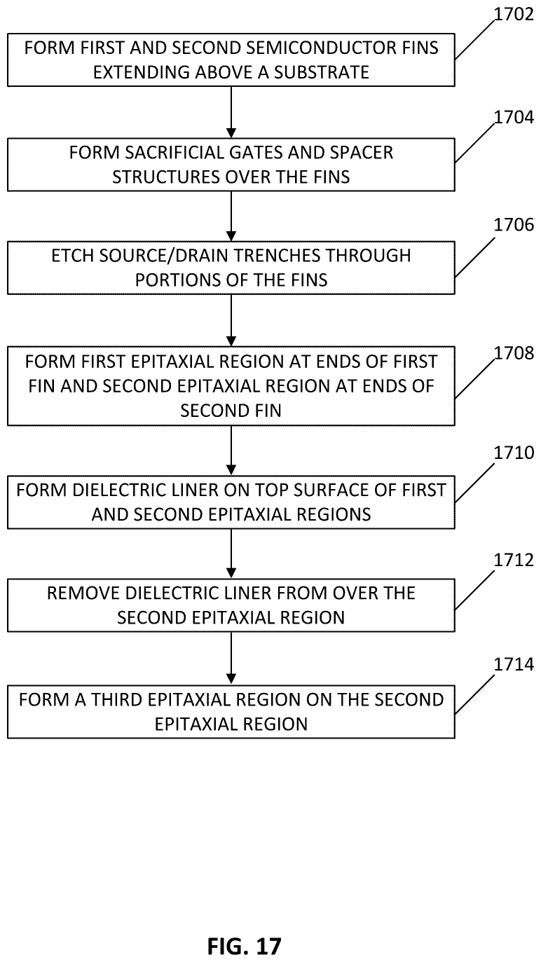

FIG. 17 is a flow chart of a method 1700 for forming at least a portion of an integrated circuit, according to an embodiment. Various operations of method 1700 may be illustrated in FIG. 2A-15A and 2B-15B. However, the correlation of the various operations of method 1700 to the specific components illustrated in the aforementioned figures is not intended to imply any structural and/or use limitations. Rather, the aforementioned figures provide one example embodiment of method 1700. Other operations may be performed before, during, or after any of the operations of method 1700. For example, method 1700 does not explicitly describe various standard processes that are usually performed to form transistor structures. Some of the operations of method 1700 may be performed in a different order than the illustrated order.

Method 1700 begins with operation 1702 where at least one semiconductor fin is formed, according to some embodiments. In an example, first and second semiconductor fins may be formed. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fin includes alternating layers of material (e.g., alternating layers of silicon and SiGe) that facilitates forming of nanowires and nanoribbons and nanosheets during a gate forming process where one type of the alternating layers are selectively etched away so as to liberate the other type of alternating layers within the channel region, so that a gate-all-around (GAA) or forksheet process can then be carried out. Again, the alternating layers can be blanket deposited and then etched into fins, or deposited into fin-shaped trenches. The fins may also include a cap structure over the top surface that is used to define the location of the fins during, for example, an RIE process. The cap structure may be a dielectric material, such as silicon nitride.

According to some embodiments, a dielectric layer is formed around subfin portions of the fins. In some examples, the anisotropic etching process used to from the fins continues into at least a portion of the underlying substrate. The etched portions of the substrate that are not under any fins may be filled with a dielectric fill to form the dielectric layer that acts as STI between adjacent fins. The dielectric layer may be any suitable dielectric material such as silicon dioxide. The subfin represents a remaining portion of the substrate flanked by the dielectric layer beneath each fin, according to some embodiments.

Method 1700 continues with operation 1704 where sacrificial gates are formed over the fins. Any number of sacrificial gates may be patterned using gate masking layers in strips that run orthogonally over the fins and parallel to one another (e.g., forming a cross-hatch pattern). The gate masking layers may be any suitable hard mask material, such as carbon hard mask (CHM) or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may be any suitable dielectric material, such as silicon nitride or silicon oxynitride.

Method 1700 continues with operation 1706 where portions of the fins adjacent to the sacrificial gate and spacer structures (e.g., not covered by the sacrificial gate and spacer structures) are removed to create source/drain trenches. Any exposed portions of the fin not covered by the sacrificial gate or spacer structures may be removed using any anisotropic etching process, such as RIE. According to some embodiments, the etch continues past the height of the fin into the subfin such that a recess is etched into the subfin (and possibly further into the bulk substrate) adjacent to the remaining portion of the fin. According to some embodiments, a first source/drain trench through the first fin has a first width and a second source/drain trench through the second fin has a second width that is greater than the first width, such as at least 1.5 times, at least 2 times, at least 2.5 times, or at least 3 times greater.

Method 1700 continues with operation 1708, where a first epitaxial region is formed at the ends of the semiconductor material of the first fin and a second epitaxial region is formed at the ends of the semiconductor material of the second fin. According to some embodiments, the first and second epitaxial regions include any number of epitaxial layers. The first epitaxial region may be formed within the first source/drain trench and the second epitaxial region may be formed within the second source/drain trench. The first and second epitaxial regions may have the same layer structure and material composition as they are formed at the same time. For example, epitaxial growth of undoped semiconductor material from the ends of the semiconductor material of the first and second fins forms a first epitaxial layer along sidewall portions of the first and second source/drain trenches. Additionally, a second epitaxial layer may be formed on the first epitaxial layer to complete the formation of the first and second epitaxial regions. Each of the first and second epitaxial regions includes the same first and second epitaxial layers, according to some embodiments.

According to some embodiments, the second epitaxial layer is grown from all exposed surfaces of the first epitaxial layer and includes a doped semiconductor material (e.g., Si doped with n-type dopant or SiGe doped with p-type dopant). According to some embodiments, the second epitaxial layer substantially fills any remaining space within the first source/drain trench between adjacent fins. However, due at least in part to the greater width of the second source/drain trench, the second epitaxial layer does not fill the space within the second source/drain trench between adjacent fins.

In some embodiments, the first epitaxial layer and the second epitaxial layer are formed at separate times, such that there is a clear step discontinuity in the doping concentration between zero dopant concentration in the first epitaxial layer and the doping concentration found in the second epitaxial layer. In some embodiments, a dopant concentration gradient exists across the boundary between the first epitaxial layer and the second epitaxial layer, such that the doping concentration gradually increases from zero dopant concentration in the first epitaxial layer to the dopant concentration within the second epitaxial layer.

Method 1700 continues with operation 1710 where a dielectric liner is formed over at least the top surface of both the first and second epitaxial regions. According to some embodiments, the dielectric liner may be any suitable dielectric material, such as silicon dioxide. In some examples, the dielectric liner is deposited using any suitable conformal deposition technique, such as CVD, PECVD, or ALD. The dielectric liner may have a thickness between about 2 nm and about 5 nm, or have a thickness up to 10 nm. In some examples, the dielectric liner forms on any exposed surfaces of the first and second epitaxial regions, including any exposed side surfaces of the first and second epitaxial regions.

Method 1700 continues with operation 1712 where the dielectric liner is selectively removed from being on the second epitaxial region. According to some embodiments, the dielectric liner is patterned using suitable lithography techniques to remove the liner from being on the second epitaxial region while keeping the dielectric liner on the first epitaxial region. Accordingly, the second epitaxial region is exposed within the second source/drain trench.

Method 1700 continues with operation 1714 where a third epitaxial region is formed on the second epitaxial region within the second source/drain trench. According to some embodiments, the third epitaxial region includes any number of epitaxial layers and substantially fills any remaining space within the second source/drain trench between adjacent fins. According to some embodiments, a visible seam is present at the boundary between the second epitaxial region and the third epitaxial region. In some examples, the third epitaxial region includes a third epitaxial layer and a fourth epitaxial layer on the third epitaxial layer. The third epitaxial layer may be substantially similar to the first epitaxial layer described above, and the fourth epitaxial layer may be substantially similar to the second epitaxial layer described above. As such, the third epitaxial layer may include a substantially undoped semiconductor material (e.g., Si or SiGe), and the fourth epitaxial layer may include a doped semiconductor material (e.g., having the same dopant as the second epitaxial layer). In some examples, the second epitaxial layer and the fourth epitaxial layer have the same dopant concentration of either n-type or p-type dopant.

In some embodiments, the third epitaxial layer and the fourth epitaxial layer are formed at separate times, such that there is a clear step discontinuity in the doping concentration between zero dopant concentration in the third epitaxial layer and the doping concentration found in the fourth epitaxial layer. In some embodiments, a dopant concentration gradient exists across the boundary between the third epitaxial layer and the fourth epitaxial layer, such that the doping concentration gradually increases from zero dopant concentration in the third epitaxial layer to the dopant concentration within the fourth epitaxial layer.

### Example System

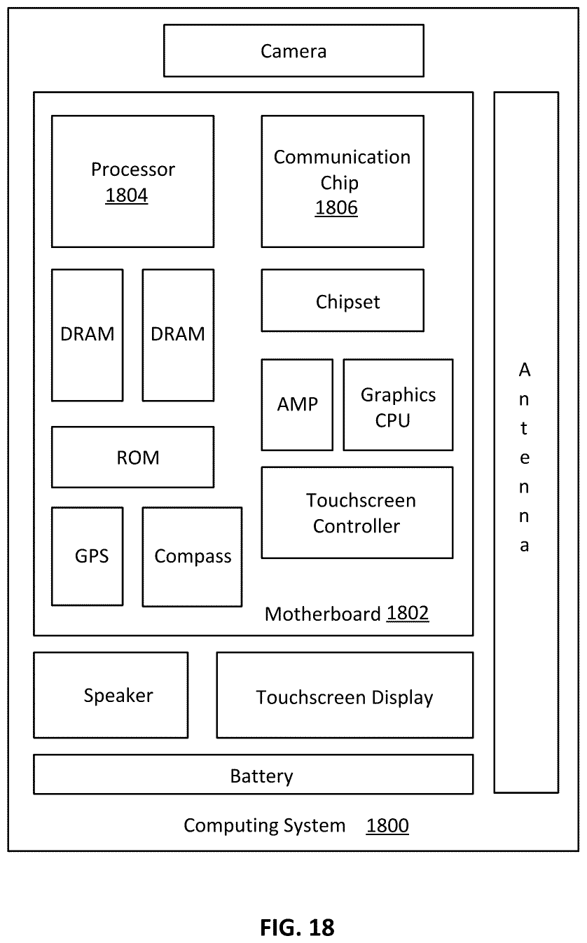

FIG. 18 is an example computing system implemented with one or more of the integrated circuit structures as disclosed herein, in accordance with some embodiments of the present disclosure. As can be seen, the computing system 1800 houses a motherboard 1802. The motherboard 1802 may include a number of components, including, but not limited to, a processor 1804 and at least one communication chip 1806, each of which can be physically and electrically coupled to the motherboard 1802, or otherwise integrated therein. As will be appreciated, the motherboard 1802 may be, for example, any printed circuit board (PCB), whether a main board, a daughterboard mounted on a main board, or the only board of system 1800, etc.

Depending on its applications, computing system 1800 may include one or more other components that may or may not be physically and electrically coupled to the motherboard 1802. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1800 may include one or more integrated circuit structures or devices configured in accordance with an example embodiment (e.g., a module including an integrated circuit configured with different semiconductor devices having source or drain regions with different epitaxial growth profiles, as variously provided herein). In some embodiments, multiple functions can be integrated into one or more chips (e.g., for instance, note that the communication chip 1806 can be part of or otherwise integrated into the processor 1804).

The communication chip 1806 enables wireless communications for the transfer of data to and from the computing system 1800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1806 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1800 may include a plurality of communication chips 1806. For instance, a first communication chip 1806 may be dedicated to shorter range wireless communications such as Wi-Fi and Bluetooth and a second communication chip 1806 may be dedicated to longer range wireless communications such as GPS, EDGE, GPRS, CDMA, WiMAX, LTE, Ev-DO, and others.

The processor 1804 of the computing system 1800 includes an integrated circuit die packaged within the processor 1804. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1806 also may include an integrated circuit die packaged within the communication chip 1806. In accordance with some such example embodiments, the integrated circuit die of the communication chip includes one or more semiconductor devices as variously described herein. As will be appreciated in light of this disclosure, note that multi-standard wireless capability may be integrated directly into the processor 1804 (e.g., where functionality of any chips 1806 is integrated into processor 1804, rather than having separate communication chips). Further note that processor 1804 may be a chip set having such wireless capability. In short, any number of processor 1804 and/or communication chips 1806 can be used. Likewise, any one chip or chip set can have multiple functions integrated therein.

In various implementations, the computing system 1800 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1800 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a semiconductor device having a semiconductor region extending in a first direction from a source or drain region and a gate structure extending in a second direction over the semiconductor region. The source or drain region has a width along the first direction that is greater than 50 nm and includes a first epitaxial region on at least a portion of the semiconductor region and a second epitaxial region on the first epitaxial region. Each of the first epitaxial region and second epitaxial region includes n-type or p-type dopant.

Example 2 includes the integrated circuit of Example 1, wherein the width of the source or drain region is between 50 nm and 60 nm.

Example 3 includes the integrated circuit of Example 1 or 2, wherein the first epitaxial region comprises a first epitaxial layer and a second epitaxial layer on the first epitaxial layer.

Example 4 includes the integrated circuit of Example 3, wherein the first epitaxial layer contacts the at least a portion of the semiconductor region, and the second epitaxial layer comprises the n-type or p-type dopant.

Example 5 includes the integrated circuit of Example 4, wherein the first epitaxial layer is substantially undoped

Example 6 includes the integrated circuit of Example 4 or 5, wherein the second epitaxial region comprises a third epitaxial layer and a fourth epitaxial layer on the third epitaxial layer.

Example 7 includes the integrated circuit of Example 6, wherein the third epitaxial layer is on the second epitaxial layer, and the fourth epitaxial layer comprises the n-type or p-type dopant.

Example 8 includes the integrated circuit of Example 7, wherein the first and third epitaxial layers are each substantially undoped.

Example 9 includes the integrated circuit of any one of Examples 1-8, further comprising a backside contact extending through a bottom surface of the source or drain region.

Example 10 includes the integrated circuit of any one of Examples 1-9, wherein the semiconductor region comprises a plurality of semiconductor nanoribbons. In other examples, the semiconductor region comprises a plurality of semiconductor nanowires, or a combination of nanowires and nanoribbons.

Example 11 includes the integrated circuit of Example 10, wherein the plurality of semiconductor nanoribbons (and/or other semiconductor regions) comprise germanium, silicon, or a combination thereof.

Example 12 includes the integrated circuit of any one of Examples 1-11, wherein a visible seam is present between the first epitaxial region and the second epitaxial region.

Example 13 is a die that includes the integrated circuit of any one of Examples 1-12.

Example 14 is an electronic device that includes a chip package having one or more dies. At least one of the one or more dies includes a plurality of semiconductor nanoribbons extending in a first direction from a source or drain region, a gate structure extending in a second direction over the plurality of semiconductor nanoribbons, and a backside contact extending through a bottom surface of the source or drain region. The source or drain region has a width along the first direction that is greater than 50 nm and includes a first epitaxial region on at least a portion of the plurality of semiconductor nanoribbons and a second epitaxial region on the first epitaxial region. Each of the first epitaxial region and second epitaxial region includes n-type or p-type dopant.

Example 15 includes the electronic device of Example 14, wherein the width of the source or drain region is between 50 nm and 60 nm.

Example 16 includes the electronic device of Example 14 or 15, wherein the first epitaxial region comprises a first epitaxial layer and a second epitaxial layer on the first epitaxial layer.

Example 17 includes the electronic device of Example 16, wherein the first epitaxial layer contacts the at least a portion of the plurality of semiconductor nanoribbons, and the second epitaxial layer comprises the n-type or p-type dopant.

Example 18 includes the electronic device of Example 17, wherein the first epitaxial layer is substantially undoped.

Example 19 includes the electronic device of Example 17 or 18, wherein the second epitaxial region comprises a third epitaxial layer and a fourth epitaxial layer on the third epitaxial layer.

Example 20 includes the electronic device of Example 19, wherein the third epitaxial layer is on the second epitaxial layer, and the fourth epitaxial layer comprises the n-type or p-type dopant.

Example 21 includes the electronic device of Example 20, wherein the first and third epitaxial layers are each substantially undoped.

Example 22 includes the electronic device of any one of Examples 14-21, wherein the backside contact extends through an entire thickness of the first epitaxial region and into at least a portion of the second epitaxial region.

Example 23 includes the electronic device of any one of Examples 14-22, wherein the plurality of semiconductor nanoribbons comprise germanium, silicon, or a combination thereof.

Example 24 includes the electronic device of any one of Examples 14-23, wherein a visible seam is present between the first epitaxial region and the second epitaxial region.

Example 25 includes the electronic device of any one of Examples 14-24, further comprising a printed circuit board, wherein the chip package is coupled to the printed circuit board.

Example 26 is a method of forming an integrated circuit. The method includes: forming a first fin and a second fin each comprising semiconductor material, the first and second fins extending above a substrate; forming sacrificial gates and spacer structures over the first and second fins; removing portions of the first and second fins not covered by the sacrificial gates and spacer structures; forming a first epitaxial region at exposed ends of the semiconductor material of the first fin and a second epitaxial region at exposed ends of the semiconductor material of the second fin; forming a dielectric liner on the top surface of the first epitaxial region and the second epitaxial region; removing the dielectric liner from the top surface of the second epitaxial region; forming a third epitaxial region on the second epitaxial region after removing the dielectric liner from the top surface of the second epitaxial region; and removing the dielectric liner from the top surface of the first epitaxial region.

Example 27 includes the method of Example 26, wherein the first epitaxial region has a width that is at least twice as small as a width of the second epitaxial region.

Example 28 includes the method of Example 26 or 27, further comprising: removing at least a portion of the substrate; and forming a backside contact through a bottom surface of the second epitaxial region.

Example 29 includes the method of Example 28, wherein the backside contact extends through the second epitaxial region and through at least a portion of the third epitaxial region.

Example 30 includes the method of any one of Examples 26-29, wherein forming the first epitaxial region and the second epitaxial region comprises forming the epitaxial regions at the same time.

Example 31 is an integrated circuit that includes a first semiconductor device having a first semiconductor region extending in a first direction from a first source or drain region and a first gate structure extending in a second direction over the first semiconductor region, and a second semiconductor device having a second semiconductor region extending in the first direction from a second source or drain region and a second gate structure extending in a second direction over the second semiconductor region. The second source or drain region has a width that is at least twice as large as a width of the first source or drain region along the first direction. The second source or drain region includes a first epitaxial region on at least a portion of the second semiconductor region and a second epitaxial region on the first epitaxial region. Each of the first epitaxial region and second epitaxial region includes n-type or p-type dopant.

Example 32 includes the integrated circuit of Example 31, wherein the width of the second source or drain region is between 50 nm and 60 nm.

Example 33 includes the integrated circuit of Example 31 or 32, wherein the first epitaxial region comprises a first epitaxial layer and a second epitaxial layer on the first epitaxial layer.

Example 34 includes the integrated circuit of Example 33, wherein the first epitaxial layer contacts the at least a portion of the second semiconductor region, and the second epitaxial layer comprises the n-type or p-type dopant.

Example 35 includes the integrated circuit of Example 34, wherein the first epitaxial layer is substantially undoped.

Example 36 includes the integrated circuit of Example 34 or 35, wherein the second epitaxial region comprises a third epitaxial layer and a fourth epitaxial layer on the third epitaxial layer.

Example 37 includes the integrated circuit of Example 36, wherein the third epitaxial layer is on the second epitaxial layer, and the fourth epitaxial layer comprises the n-type or p-type dopant.

Example 38 includes the integrated circuit of Example 37, wherein the first and third epitaxial layers are each substantially undoped.

Example 39 includes the integrated circuit of any one of Examples 31-38, further comprising a backside contact extending through a bottom surface of the second source or drain region.

Example 40 includes the integrated circuit of Example 39, wherein the backside contact extends through an entire thickness of the first epitaxial region and into at least a portion of the second epitaxial region.

Example 41 includes the integrated circuit of any one of Examples 31-40, wherein the first semiconductor region comprises a first plurality of semiconductor nanoribbons, and the second semiconductor region comprises a second plurality of semiconductor nanoribbons. In other examples, one or each of the first and second semiconductor regions comprises a combination of nanowires and nanoribbons, or a plurality of semiconductor nanowires.

Example 42 includes the integrated circuit of Example 41, wherein the first plurality of semiconductor nanoribbons and the second plurality of semiconductor nanoribbons comprise germanium, silicon, or a combination thereof. Similar composition may apply to other channel feature geometries such as nanowires, as described above.

Example 43 includes the integrated circuit of any one of Examples 31-42, wherein a visible seam is present between the first epitaxial region and the second epitaxial region.

Example 44 is a die that includes the integrated circuit of any one of Examples 31-43.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having a semiconductor region extending in a first direction from a source or drain region, and a gate structure extending in a second direction over the semiconductor region;
wherein the source or drain region has a width along the first direction that is greater than 50 nm and comprises a first epitaxial region on at least a portion of the semiconductor region and a second epitaxial region on the first epitaxial region, each of the first epitaxial region and second epitaxial region comprising n-type or p-type dopant.

2. The integrated circuit of claim 1, wherein the first epitaxial region comprises a first epitaxial layer and a second epitaxial layer on the first epitaxial layer.

3. The integrated circuit of claim 2, wherein the first epitaxial layer contacts the at least a portion of the semiconductor region, and the second epitaxial layer comprises the n-type or p-type dopant.

4. The integrated circuit of claim 3, wherein the first epitaxial layer is substantially undoped.

5. The integrated circuit of claim 3, wherein the second epitaxial region comprises a third epitaxial layer and a fourth epitaxial layer on the third epitaxial layer.

6. The integrated circuit of claim 5, wherein the third epitaxial layer is on the second epitaxial layer, and the fourth epitaxial layer comprises the n-type or p-type dopant.

7. The integrated circuit of claim 1, further comprising a backside contact extending through a bottom surface of the source or drain region.

8. The integrated circuit of claim 1, wherein a visible seam is present between the first epitaxial region and the second epitaxial region.

9. A die comprising the integrated circuit of claim 1.

10. An electronic device, comprising:
a chip package comprising one or more dies, at least one of the one or more dies comprising
a plurality of semiconductor nanoribbons extending in a first direction from a source or drain region;
a gate structure extending in a second direction over the plurality of semiconductor nanoribbons; and
a backside contact extending through a bottom surface of the source or drain region;
wherein the source or drain region has a width along the first direction that is greater than 50 nm and comprises a first epitaxial region on at least a portion of the plurality of semiconductor nanoribbons and a second epitaxial region on the first epitaxial region, each of the first epitaxial region and second epitaxial region comprising n-type or p-type dopant.

11. The electronic device of claim 10, wherein the first epitaxial region comprises a first epitaxial layer and a second epitaxial layer on the first epitaxial layer.

12. The electronic device of claim 11, wherein the first epitaxial layer contacts the at least a portion of the plurality of semiconductor nanoribbons, and the second epitaxial layer comprises the n-type or p-type dopant.

13. The electronic device of claim 12, wherein the first epitaxial layer is substantially undoped.

14. The electronic device of claim 10, wherein the backside contact extends through an entire thickness of the first epitaxial region and into at least a portion of the second epitaxial region.

15. An integrated circuit comprising:
a first semiconductor device having a first semiconductor region extending in a first direction from a first source or drain region, and a first gate structure extending in a second direction over the first semiconductor region; and
a second semiconductor device having a second semiconductor region extending in the first direction from a second source or drain region, and a second gate structure extending in a second direction over the second semiconductor region, the second source or drain region having a width that is at least twice as large as a width of the first source or drain region along the first direction;
wherein the second source or drain region comprises a first epitaxial region on at least a portion of the second semiconductor region and a second epitaxial region on the first epitaxial region, each of the first epitaxial region and second epitaxial region comprising n-type or p-type dopant.

16. The integrated circuit of claim 15, wherein the first epitaxial region comprises a first epitaxial layer and a second epitaxial layer on the first epitaxial layer.

17. The integrated circuit of claim 16, wherein the first epitaxial layer contacts the at least a portion of the second semiconductor region, and the second epitaxial layer comprises the n-type or p-type dopant.

18. The integrated circuit of claim 17, wherein the first epitaxial layer is substantially undoped.

19. The integrated circuit of claim 15, further comprising a backside contact extending through a bottom surface of the second source or drain region.

20. The integrated circuit of claim 19, wherein the backside contact extends through an entire thickness of the first epitaxial region and into at least a portion of the second epitaxial region.
